(19) United States
(12) Patent Application Publication
(10) Pub. No.: US 2024/0313768 A1
(43) Pub. Date: Sep. 19, 2024

(54) HIGH VOLTAGE POWER STAGE USING LOW VOLTAGE TRANSISTORS

(71) Applicant: Texas Instruments Incorporated, Dallas, TX (US)

(72) Inventors: Sri Navaneethakrishnan Easwaran, Plano, TX (US); Angelo Pereira, Allen, TX (US); Yueming Sun, SHANGHAI (CN); Kae Wong, ALLEN, TX (US); Ahmed E Hashim, GILBERT, AZ (US); Artur Lewinski, Dallas, TX (US)

(21) Appl. No.: 18/306,378

(22) Filed: Apr. 25, 2023

Related U.S. Application Data
(60) Provisional application No. 63/452,239, filed on Mar. 15, 2023.

(51) Int. Cl. H03K 17/687; H03K 17/10; H03K 17/567

(52) U.S. Cl. CPC H03K 17/687; H01L 27/02; H03K 17/102; H03K 17/567

(57) ABSTRACT

Described embodiments include a voltage converter power circuit having a high-voltage rated first transistor with a first current terminal coupled to an input voltage terminal, and a second current terminal. A second transistor, a low-voltage rated transistor, has a second control terminal, a third current terminal coupled to the second current terminal, and a fourth current terminal coupled to a switching terminal. A third transistor, a high-voltage rated transistor, has a fifth current terminal coupled to the switching terminal, a sixth current terminal, and a third control terminal. A fourth transistor, a low-voltage rated transistor, is coupled between the sixth current terminal and a ground terminal. A bleeder circuit is coupled between the seventh and eighth current terminals and is configured to prevent a voltage across the fourth transistor from exceeding a breakdown voltage.

### CROSS-REFERENCE TO RELATED APPLICATION

This application claims priority to U.S. Provisional Patent Application No. 63/452,239 filed Mar. 15, 2023, which is incorporated herein by reference.

### BACKGROUND

This description relates to switching power converters. Power transistors may be used in a power stage of a switching power converter. A power transistor is usually specified to be able to withstand a first particular voltage across its two current terminals (e.g. drain and source) when the transistor is turned on without sustaining damage. The power transistor is usually specified to be able to withstand a second particular voltage, usually higher than the first voltage, across the two current terminals when the transistor turned off without sustaining damage.

In some cases, such as in some automotive battery applications, a transistor in a switching regulator may be specified to switch up to 40 volts. If voltage overshoot margin for transients is included, the transistor may be specified to withstand 45-50 volts without sustaining damage. However, transistors capable of withstanding high voltages usually require significantly more area than low voltage transistors, and high voltage transistors also consume more power than low voltage transistors. Furthermore, the gate drive circuits used to drive the larger, higher voltage transistors may also be significantly larger in area and higher in power consumption than gate drive circuits for lower voltage transistors, further exacerbating the problem.

### SUMMARY

In a first example, a power circuit for a voltage converter includes a first transistor having first and second current terminals and a first control terminal. The first current terminal is coupled to an input voltage terminal. The first transistor is a high-voltage rated transistor. A second transistor has third and fourth current terminals and a second control terminal. The third current terminal is coupled to the second current terminal. The fourth current terminal is coupled to a switching terminal. The second transistor is a low-voltage rated transistor.

A third transistor has fifth and sixth current terminals and a third control terminal. The fifth current terminal is coupled to the switching terminal. The third transistor is a high-voltage rated transistor. A fourth transistor has seventh and eighth current terminals and a fourth control terminal. The seventh current terminal is coupled to the sixth current terminal. The fourth transistor is a low-voltage rated transistor. A bleeder circuit is coupled between the seventh and eighth current terminals. The bleeder circuit is configured to prevent a voltage across the fourth transistor from exceeding a breakdown voltage.

In a second example, an integrated circuit includes a substrate having a first conductivity type. A diffusion layer is disposed upon the substrate, wherein the diffusion layer has a second conductivity type, and the diffusion layer is electrically unconnected and has a floating voltage. A bulk layer is disposed upon the diffusion layer, and the bulk layer has the first conductivity type. A doped well is disposed upon the bulk layer, and the doped well has the second conductivity type. A gate terminal is disposed upon the bulk layer, wherein the gate terminal is electrically isolated from the doped well.

In a third example, a method for manufacturing an integrated circuit includes forming a substrate having a first conductivity type. A diffusion layer is formed upon the substrate, wherein the diffusion layer has a second conductivity type, and the diffusion layer is electrically unconnected and has a floating voltage.

A bulk layer is formed upon the diffusion layer, and the bulk layer has the first conductivity type. A doped well is formed upon the bulk layer, wherein the doped well has the second conductivity type. A gate terminal is formed upon the bulk layer, and the gate terminal is electrically isolated from the doped well.

### BRIEF DESCRIPTION OF THE DRAWINGS

FIG. 1 shows a schematic diagram for an example DC-DC power converter.

FIG. 2 shows a schematic diagram for an example power stage having stacked high side and low side transistors.

FIG. 3 shows a schematic diagram for an example bleeder circuit.

FIG. 4 shows a cross-section for an example transistor having an isolating N-buried layer (NBL).

FIG. 5 shows a schematic diagram for an example power stage low-side circuit having a transistor with a floating NBL.

FIG. 6 shows a schematic diagram for an example power stage low-side circuit having a transistor with a resistor coupled between the isolation terminal and ground.

FIG. 7 shows a schematic diagram for an example power stage low-side circuit 700 having a transistor with a zener diode coupled between the drain terminal and the isolation terminal.

### DETAILED DESCRIPTION

In this description, the same reference numbers depict same or similar (by function and/or structure) features. The drawings are not necessarily drawn to scale.

Power transistors that are used in switching converters, or in other applications that require a high voltage transistor, are usually field effect transistors (FETs). However, other types of transistors, such as bipolar transistors, may be used instead. If a bipolar transistor is used, the base, collector and emitter may be substituted for the gate, drain and source, respectively.

A transistor having a low on-resistance, RpSON, may have improved power efficiency duc to lower power consumption. However, many semiconductor processes that support a low RDSON may not support high voltage applications. Conversely, many semiconductor processes that support high voltage applications may have a higher RDSON, thereby increasing the power consumption. Some systems that use switching power converters may have transients that bring the voltage up to 45-50V on the battery or input voltage supply line.

For this reason, the FETs that are used in the power converter may need to be capable of withstanding a high voltage from drain to source. As an example, the battery supply voltage in automotive applications may nominally be 35V, and the circuits powered by the battery may be required to be fully functional in the turned-on state at 35V from source to drain. Although the FETs in the circuit may be able to be turned off when the supply voltage gets above 35V, the FETs may still be required to withstand 40V (or more) from drain to source in the off state without sustaining damage.

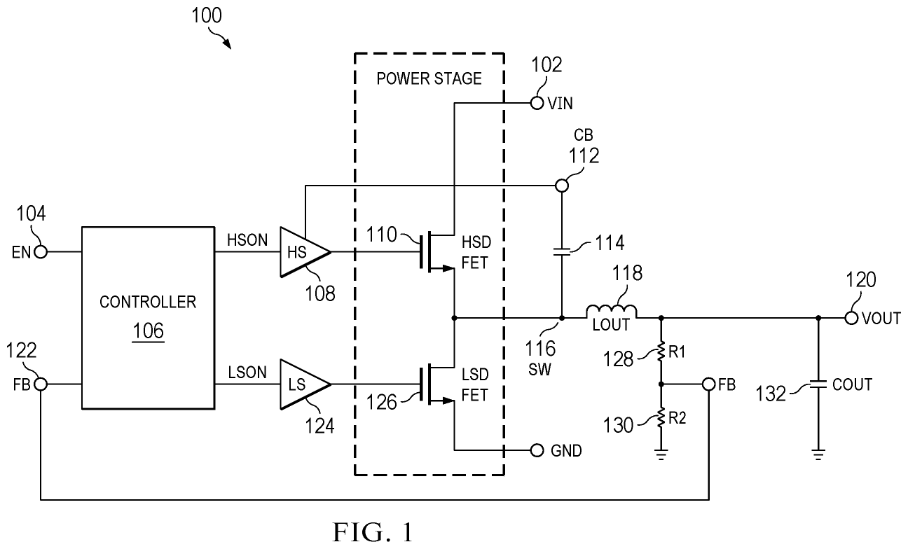

FIG. 1 shows a schematic diagram for an example DC-DC power converter 100. The input voltage terminal VIN 102 receives a DC voltage that is to be regulated to a specified output voltage and provided at the output voltage terminal VOUT 120. The input voltage at the input voltage terminal VIN 102 may be supplied by a battery or by some other DC power source. A power stage includes transistors 110 and 126, which are coupled in series between the input voltage terminal VIN 102 and a ground terminal GND. Transistors 110 and 126 are driven by high side driver 108 and low side driver 124, respectively, which are each controlled by controller 106.

Transistor 110 is coupled between input voltage terminal VIN 102 and a switching terminal SW 116. Transistor 126 is coupled between the switching terminal SW 116 and the ground terminal GND. A first input of controller 106 is coupled to enable terminal EN 104, which may receive an enable signal from a system control device (not shown). A second input of controller 106 is coupled to a feedback terminal FB 122.

A first output of controller 106 is coupled to the input of high side driver 108. A second output of controller 106 is coupled to the input of low side driver 124. The output of high side driver 108 is coupled to the gate of transistor 110 and provides a switching signal for turning transistor 110 off and on. The output of low side driver 124 is coupled to the gate of transistor 126 and provides a switching signal for turning transistor 126 off and on. Controller 106 controls the duration and timing for when transistor 110 and transistor 126 are on, and ensures that transistors 110 and 126 are never turned on at the same time to prevent a short circuit between the input voltage terminal VIN 102 and the ground terminal GND.

A bootstrap capacitor 114 is coupled between a boost terminal 112 and the switching terminal SW 116. The boost terminal 112 is coupled to the supply terminal of high side driver 108 and can provide a voltage that is higher than the voltage at the input voltage terminal VIN 102. The boosted voltage at the supply terminal of high side driver 108 allows the proper operation of transistor 110, which is an n-channel FET (NFET) by providing a voltage to the gate of transistor 110 that is higher than the voltage at the input voltage terminal VIN 102.

Inductor 118 is coupled between the switching terminal SW 116 and the output voltage terminal VOUT 120. Resistors 128 and 130 are coupled in series between the output voltage terminal VOUT 120 and ground. The feedback terminal FB 122 is coupled to the connection between resistors 128 and 130. Capacitor 132 is coupled between the output voltage terminal VOUT 120 and ground.

Controller 106 receives an enable signal from the enable terminal EN 104. When the enable signal is asserted, controller 106 provides control signals HSON and LSON at its outputs. HSON controls turning transistor 110 off and on through high side driver 108. The signal LSON controls turning transistor 126 off and on through low side driver 124. Controller 106 generates the signals HSON and LSON to maintain a particular voltage at the output voltage terminal VOUT 120 in response to the voltage at feedback terminal FB 122, which is proportional to the voltage at the output voltage terminal VOUT 120.

Some applications using switching regulators, such as automotive battery-connected switching regulators are specified to switch at or withstand up to 40V, which requires that the transistors used in the power stage operate at a voltage range based on having a 40V supply voltage plus 5-10 V overshoot margin for transients, or about 45-50V. A common design approach for meeting this specification is using a process technology that is rated for 40V or higher for fabricating the switching regulator power stage components.

However, using higher voltage processes may lead to lower performance characteristics of the components, such as having higher on-resistance, RDSON, lower power efficiency, slower transient response, and a larger area, which can lead to higher cost. This is a trade-off in supporting the specified higher voltage. Conversely, lower voltage processes having better electrical performance may not support the higher voltage requirement.

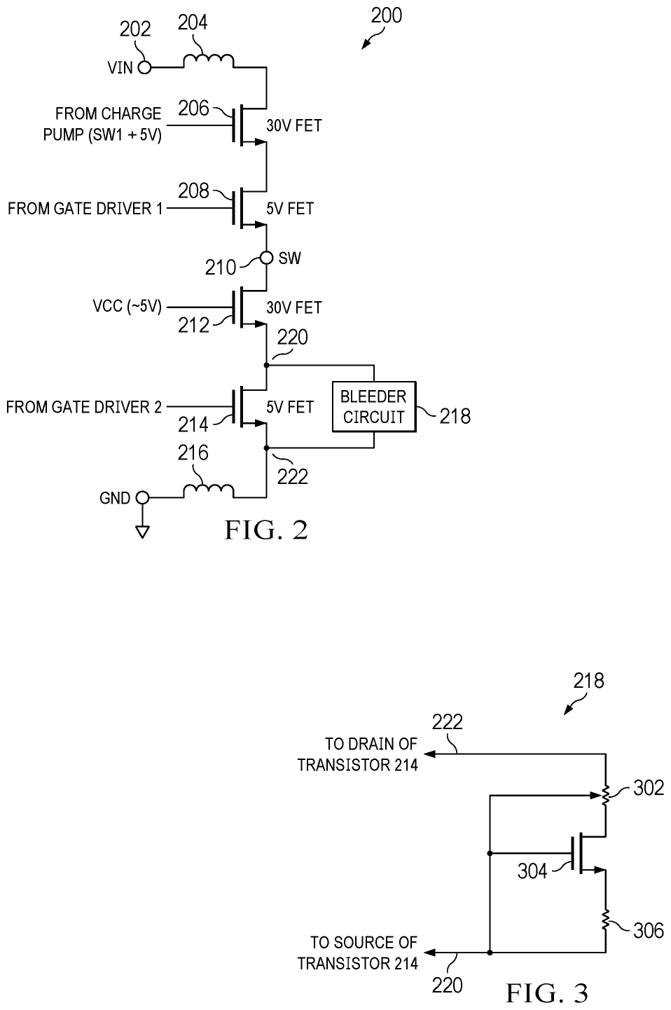

FIG. 2 shows a schematic diagram for an example power stage 200 having stacked high side and low side transistors. This stacked transistor configuration can be useful in switching power regulators and other applications that have a requirement to operate with higher input voltages. The input voltage terminal VIN 202 receives a DC voltage that is to be regulated down to a specified output voltage. The voltage at the input voltage terminal VIN 202 may be supplied by a battery or some other type of DC power source. In at least one case, the input voltage is nominally 35V, but may have a 5-10V transient on top of the nominal voltage. In this case, the FETs in the power stage may be required to operate at 35V, and to withstand 40V (or more) in the off state without sustaining damage.

Power stage 200 includes transistors 206, 208, 212 and 214. Transistors 206 and 212 are 30V NFETs, and transistors 208 and 214 are 5V NFETs. Transistor 208 receives a first pulse width modulated (pwm) signal at its gate from a first gate driver circuit (not shown). Transistor 214 receives a second pwm signal at its gate from a second gate driver circuit (not shown). The first pwm signal received at the gate of transistor 208 is 180 degrees out of phase with the second pwm signal received at the gate of transistor 214. Transistors 208 and 214 perform a switching function in the power regulator to maintain the specified regulated voltage at the output voltage terminal. Transistors 206 and 212 provide high voltage protection of transistors 208 and 214, respectively.

The source of transistor 206 is coupled to the input voltage terminal VIN 202. A small parasitic inductance 204 (˜3 nH) may be present due to a bond wire or other means for connecting the source of transistor 206 to the input voltage terminal VIN 202. The gate of transistor 206 is coupled to the output of a charge pump circuit that provides a constant DC voltage that in this case is equal to the voltage at switching terminal SW 210 plus 5V. The boosted bias voltage from the charge pump that is provided to the gate of transistor 206 is necessary to turn on transistor 206, because transistor 206 is an n-channel FET and the voltage at the source of transistor 206 is at the voltage of the input voltage terminal VIN 202.

The drain of transistor 206 is coupled to the source of transistor 208, and the drain of transistor 208 is coupled to the switching terminal SW 210. The first pwm signal has a varying duty cycle that is provided to the gate of transistor 208, causing transistor 208 to turn on and off, alternately connecting the voltage at the input voltage terminal VIN 202 to the switching terminal SW 210. The duty cycle of the first and second pwm signals are adjusted dynamically as the circuit operates to maintain the specified voltage at the power converter output terminal.

The source of transistor 212 is coupled to the switching terminal SW 210. The gate of transistor 212 can be biased with a DC voltage (e.g. 5V) to ensure that it turns on and conducts whenever transistor 214 is turned on. The drain of transistor 212 is coupled to the source of transistor 214, and the drain of transistor 214 is coupled to the ground terminal GND. A small parasitic inductance 216 (˜3 nH) may be present due to a bond wire or other means for connecting the drain of transistor 214 to the ground terminal GND.

The second pwm signal has a varying duty cycle and is provided to the gate of transistor 208, causing transistor 208 to turn on and off, alternately connecting the ground terminal GND to the switching terminal SW 210. The first and second pwm signals ensure that transistor 214 is off whenever transistor 208 is turned on, and that transistor 208 is turned off whenever transistor 214 is turned on to avoid shorting the input voltage terminal VIN 202 to GND.

Bleeder circuit 218 is coupled between the source and drain of transistor 214, which is a 5V NFET. Bleeder circuit 218 ensures that the drain-to-source voltages (VDS) across transistors 214 and 212 do not exceed their breakdown voltage limits. Without bleeder circuit 218, the leakage of transistors 212 and 214, which may be unbalanced, would determine their Vps. In cases where the voltage at the input voltage terminal VIN 202 exceeds 40V, the Vps of transistor 214 can exceed its breakdown voltage. The bleeder circuit 218 helps to maintain the Vps of transistors 212 and 214 within their break down limits or safe operating areas.

FIG. 3 shows a schematic diagram for an example bleeder circuit 218. Variable resistor 302 is coupled between the drain of transistor 214 and the source of transistor 304. Resistor 306 is coupled between the source of transistor 214 and the drain of transistor 304. Transistor 304 is an NFET having a gate coupled to a control terminal of variable resistor 302, and to the source of transistor 214.

In this case, if the voltage at the input voltage terminal VIN 202 is less than or equal to 36V, the power converter operates to regulate the output voltage down to 6V by adjusting the duty cycle of the first and second pwm signals that are provided to transistor 208 and transistor 214, respectively, through gate driver 1 (not shown) and gate driver 2 (not shown), respectively. The area and power dissipation of transistor 206, a 30V FET, and transistor 208, a 5V FET, combined is less than the area and power dissipation of a single 40V FET. Furthermore, the area and power dissipation of the driver circuit required for controlling the gate of a 5V FET is less than the arca and power dissipation of a driver circuit for controlling the gate of a 40V FET, further adding to the increased area and power efficiency from replacing a 40V FET with a stacked combination of a 30V FET and a 5V FET.

If the voltage at the input voltage terminal VIN 202 is greater than 36V but less than 40V, the power converter circuit will be turned off. However, even though the power converter circuit is turned off, the driver circuit still must be able to withstand a voltage of 36V to 40V between the input voltage terminal VIN 202 and switching terminal SW 210, and between switching terminal SW 210 and ground GND, without being damaged. If the voltage at the input voltage terminal VIN 202 is greater than 36V but less than 40V, transistors 206, 208, 212, and 214 are each turned off, which helps these transistors to withstand a transient that causes the voltage at the input voltage terminal VIN 202 to be higher than 40V. The transistors are able to withstand this voltage because the breakdown voltage (BVDSS) of each of the stacked FET pairs is higher than 40V. So, in addition to the increased area and power efficiency provided by using stacked 30V and 5V FETs in comparison to using a single 40V FET, a higher breakdown voltage can also be achieved because the breakdown voltage of the stacked FETs is the sum of the breakdown voltages of each individual FET in the stack.

However, a stacked FET circuit can also bring particular risks if a traditional FET is used. The stacked FETs may be capable of withstanding 40V at the input voltage terminal VIN 202 in the OFF state with low leakage using a traditional FET. However, in a traditional FET, the voltage at the intermediate node that connects the drain of transistor 206 to the source of transistor 208, and the voltage at the intermediate node connecting the drain of transistor 212 to the source of transistor 214, can be uncertain when the transistors are in the OFF state. The voltages at the intermediate FET connection nodes cannot be allowed to float because that can provide a reliability risk due to the leakage behavior of the 30V FET and the 5V FET not being controlled. For this reason, it is necessary to add either leakage compensation or a clamp to the FET.

When transistors 206 and 208 are turned on and transistors 212 and 214 are turned off, the voltage at switching terminal SW 210 is equal to the voltage at the input voltage terminal VIN 202. The voltage at the source terminal of transistor 206 is higher than the ISO terminal of transistor 206, which forward biases transistor 206 and turns it on. If the voltage at the intermediate FET connection node that connects transistor 206 to transistor 208 rises to the voltage at the input voltage terminal VIN 202, the drain-to-source voltage of transistor 208 can exceed its absolute maximum rated voltage and be damaged. However, leaving the voltage at the ISO terminal of transistor 212 floating can provide a solution to this problem.

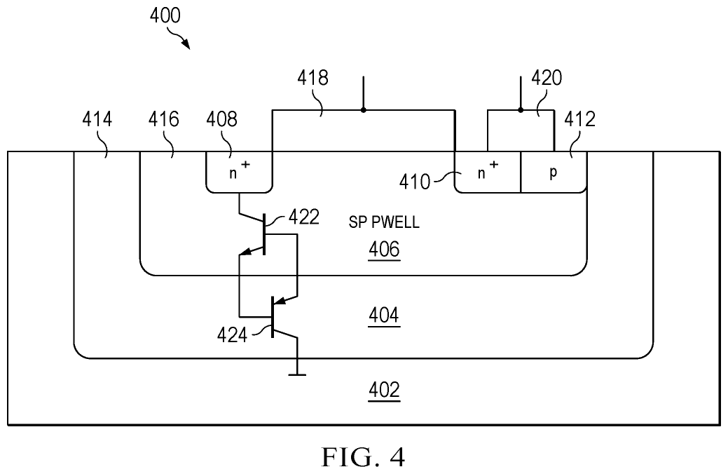

FIG. 4 shows an example cross-section for a transistor 400 having an isolating N-buried layer (NBL). Isolating NBL 404 is disposed upon P-substrate 402. Special P-well 406 is disposed upon isolating NBL 404. A n-plus doping 408 is added to the special P-well 406 and is connected to the drain 416. An n-plus doping 410 and a p-plus doping 412 are added to the special P-well 406 and are connected to the source 420. Gate 418 is formed above special P-well 406. P-substrate 402 is connected to ground.

The isolating NBL 404 of transistor 400 helps to achieve a low Rpsox while maintaining a smaller area, but results in two parasitic bipolar transistors being formed by p-n junctions. Parasitic transistor 422 is a npn transistor having a first p-n junction formed at the intersection of n-plus doping 408 with special P-well 406, and a second p-n junction formed at the intersection of special P-well 406 with isolating NBL 404. Parasitic transistor 424 is a pnp transistor having a first p-n junction formed at the intersection of special P-well 406 with isolating NBL 404, and a second p-n junction formed at the intersection of isolating NBL 404 with P-substrate 402.

Transistor 400 is an NFET, having an n-type drain and an n-type source. The bulk of transistor 400 is formed in special P-well 406. Isolating NBL 404 isolates the drain and the source from the substrate. The isolating NBL 404 is an n-type diffusion around the special P-well 406 to isolate it from the P-substrate 402. The breakdown voltage of the transistor 400 can be adjusted by varying the doping concentration. Ideally, the P-substrate 402 does not conduct any current. However, a current will flow through P-substrate 402 if the p-n junctions of parasitic transistor 422 and 424 become forward biased.

The voltages at the drain 416, source 420, and gate 418 of transistor 400 are controlled by either a pwm signal or a DC voltage, VCC. If VCC is at 5V, then the source 420 will be at 3.4V. If the voltage at the isolating NBL 404 is at 5V, then each of the p-n junctions that include isolating NBL 404 remain reverse-biased, and parasitic transistors 422 and 424 remain turned off. In this case, no current flows through P-substrate 402.

However, transistor 400 is also required to be able to withstand 35V at the drain 416 if the transistor is used in a circuit such as power stage 200 because the voltage at SW1 will switch to 35V when transistors 208 and 206 turn on. If the low side transistors are turned on and the high side transistors are off, followed by the low side transistors being turned off and the high side transistors being turned on, the p-n junction between n-plus doping 408 and the special P-well 406 will be forward-biased because there is a significant coupling between the drain 416 and the gate 418. So, the voltage at the gate 418 will rise above VCC, and the source 420 will be shorted to the special P-well 406. The p-n junction between the special P-well 406 and the isolating NBL 404 will then be forward biased because the isolating NBL is at 5V, and will begin conducting current once the voltage difference rises above approximately 0.5V in the forward direction.

Another possible solution could be to bias the isolating NBL 404 at a particular voltage. However, biasing the isolating NBL 404 at a particular voltage still carries a risk that the parasitic p-n junction between the isolating NBL 404 and the special P-well 406 will become forward-biased and conduct current. Current flow from the parasitic transistors can lead to catastrophic failures in the device.

If the voltage at isolating NBL 404 goes negative, the p-n junction between the P-substrate 403 and isolating NBL 404 will be forward-biased. If the voltage at isolating NBL 404 goes more positive than the special P-well 406 by 0.5V or more, this p-n junction will be forward-biased, turning on parasitic transistors 422 and 424 and bringing unwanted current flow through the device between the drain 416 and P-substrate 402.

Preventing current flow from parasitic transistors 422 and 424 includes avoiding forward-biasing the p-n junction between the special P-well 406 and isolating NBL 404 during switching. Leaving the voltage at the isolating NBL 404 floating so that no forward current will flow through that p-n junction can avoid this forward-biased condition includes. Leaving the voltage at the isolating NBL 404 floating will also help to withstand 35V in the on-state.

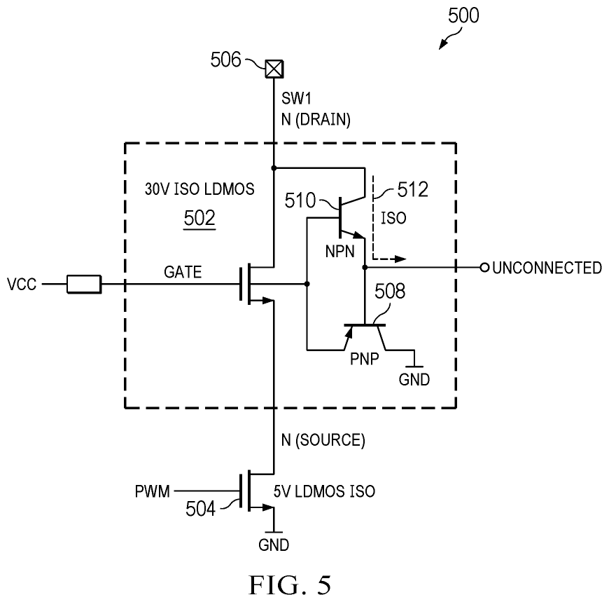

FIG. 5 shows a schematic diagram for an example power stage low-side circuit 500 having a transistor with a floating NBL. Power stage low-side circuit 500 includes transistors 502 and 504. Transistor 502 is a 30V NFET, and transistor 504 is a 5V NFET. Transistor 502 has a drain coupled to a switching terminal SW1 506 and a source coupled to the drain of transistor 504. A gate of transistor 502 is coupled to a DC bias voltage, VCC. Transistor 504 has a drain coupled to the source of transistor 502, and a source coupled to a ground terminal. A gate of transistor 504 may be coupled to a pwm signal source.

Transistor 502 includes a parasitic npn transistor 510 formed by a first p-n junction at the intersection of n-plus doping 408 with special P-well 406, and a second p-n junction at the intersection of special P-well 406 with isolating NBL 404. Transistor 502 further includes a parasitic pnp transistor formed by a first p-n junction at the intersection of special P-well 406 with isolating NBL 404, and a second p-n junction at the intersection of P-substrate 402 with isolating NBL 404.

It is desired that when transistor 502 turns on, current flows only through the drain to source channel of the device, and that no current flows through parasitic npn transistor 510 and parasitic pnp transistor 508. Furthermore, no current should flow through the drain to source channel of transistor 502 when it is turned off. When transistor 502 is switching, the voltage across transistor 502 goes from 0 to 35V because when the high side transistors turn on, the voltage at SW1 506 is pulled up to the input voltage level. When the voltage at SW1 is pulled up, capacitive coupling between the gate and the drain of transistor 502 can cause the voltage at the gate of transistor 502 to rise above VCC. The voltage at special P-well 406 is at one diode threshold below VCC. If the isolating NBL is at a voltage such as 5V, the p-n junction between special P-well 406 and the isolating NBL 404 will be forward biased. Forward-biasing this p-n junction can lead to damage of the device.

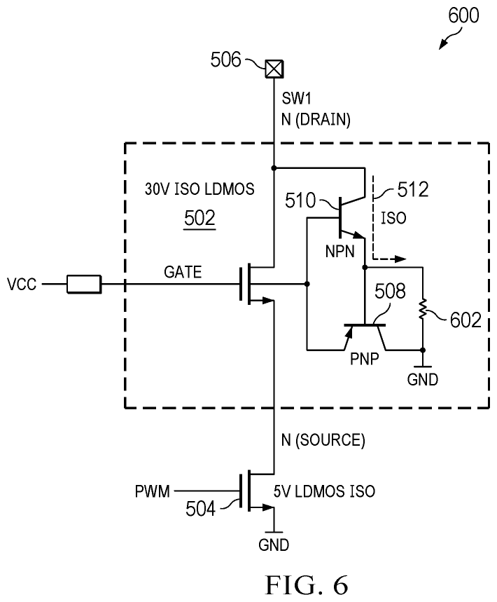

FIG. 6 shows a schematic diagram for an example power stage low-side circuit 600 having a transistor with a resistor coupled between the isolation terminal and ground. Power stage low-side circuit 500 includes transistors 502 and 504. Transistor 502 is a 30V NFET, and transistor 504 is a 5V NFET. Transistor 502 has a drain coupled to a switching terminal SW1 506 and a source coupled to the drain of transistor 504. A gate of transistor 502 is coupled to a DC bias voltage, VCC. Transistor 504 has a drain coupled to the source of transistor 502, and a source coupled to a ground terminal. A gate of transistor 504 may be coupled to a pwm signal source.

Resistor 602 is coupled between isolation terminal 512 and the ground terminal. In at least one case, resistor 602 is at least 1 Mohm to limit the current flowing to the base of parasitic transistor 508. Although limiting the base current of parasitic transistor 508 provides some increased reliability, it does not provide a complete solution because the large resistance between isolation terminal 512 and the ground terminal does not prevent parasitic transistor 508 from ever turning on.

Another possible implementation for protecting transistor 502 is to connect the isolation terminal 512 to a backgate terminal of the FET in the case of a single low-side FET coupled between SW1 terminal 506 and the ground terminal. In the case of stacked FETs, the isolation terminal can be connected a node having a different voltage than the source. However, this solution may not prevent parasitic transistors 508 and 510 from conducting current under all conditions.

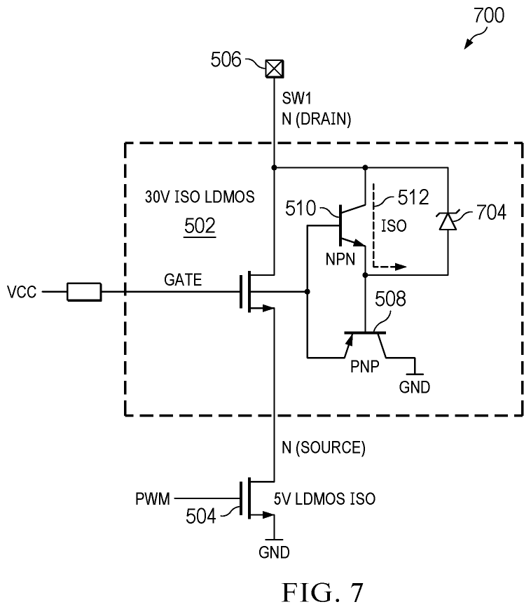

FIG. 7 shows a schematic diagram for an example power stage low-side circuit 700 having a transistor with a zener diode coupled between the drain terminal, which is connected to SW1 506, and the isolation terminal 512. This clamps the voltage across parasitic transistor 510 from the base to emitter. The voltage at the isolation terminal 512 increases with the voltage at the drain terminal when the voltage at SW1 506 rises. The voltage at the isolation terminal 512 also decreases when the voltage at SW1 506 decreases, but will never go negative because zener diode 704 keeps the voltage above the voltage at SW1 506.

To avoid damaging the FET, the isolation terminal 512 is left unconnected and its voltage is allowed to float as om FIG. 5. This ensures that the p-n junctions on each side of isolating NBL 404 remain reverse biased. Parasitic transistors 508 and 510 will remain turned off and will not conduct current as long as the p-n junctions on each side of isolating NBL 404 remain reverse biased.

In this description, “terminal,” “node.” “interconnection,” “lead” and “pin” are used interchangeably. Unless specifically stated to the contrary, these terms generally mean an interconnection between or a terminus of a device element, a circuit element, an integrated circuit, a device, or other electronics or semiconductor component.

In this description, “ground” includes a chassis ground, an Earth ground, a floating ground, a virtual ground, a digital ground, a common ground and/or any other form of ground connection applicable to, or suitable for, the teachings of this description.

In this description, the term “couple” may cover connections, communications or signal paths that enable a functional relationship consistent with this description. For example, if device A generates a signal to control device B to perform an action, then: (a) in a first example, device A is coupled to device B by direct connection; or (b) in a second example, device A is coupled to device B through intervening component C if intervening component C does not alter the functional relationship between device A and device B, so device B is controlled by device A via the control signal generated by device A.

In this description, even if operations are described in a particular order, some operations may be optional, and the operations are not necessarily required to be performed in that particular order to achieve specified results. In some examples, multitasking and parallel processing may be advantageous. Moreover, a separation of various system components in the embodiments described above does not necessarily require such separation in all embodiments.

Modifications are possible in the described embodiments, and other embodiments are possible, within the scope of the claims.

What is claimed is:

1. A power circuit for a voltage converter, the power circuit comprising:
a first transistor having first and second current terminals and a first control terminal, wherein the first transistor is a high-voltage rated transistor, and the first current terminal is coupled to an input voltage terminal;
a second transistor having third and fourth current terminals and a second control terminal, wherein the second transistor is a low-voltage rated transistor, the third current terminal is coupled to the second current terminal, and the fourth current terminal is coupled to a switching terminal;
a third transistor having fifth and sixth current terminals and a third control terminal, wherein the third transistor is a high-voltage rated transistor, and the fifth current terminal is coupled to the switching terminal;
a fourth transistor having seventh and eighth current terminals and a fourth control terminal, wherein the fourth transistor is a low-voltage rated transistor, and the seventh current terminal is coupled to the sixth current terminal; and
a bleeder circuit coupled between the seventh and eighth current terminals, wherein the bleeder circuit is configured to prevent a voltage across the fourth transistor from exceeding a breakdown voltage.

2. The power circuit of claim 1, wherein the first control terminal is coupled to a charge pump.

3. The power circuit of claim 2, wherein the voltage at the first control terminal is equal to the voltage at the switching terminal plus a constant DC voltage.

4. The power circuit of claim 1, further comprising:
a first gate drive circuit having a first gate drive output coupled to the second control terminal; and
a second gate drive circuit having a second gate drive output coupled to the fourth control terminal.

5. The power circuit of claim 1, wherein the bleeder circuit includes:
a fifth transistor having ninth and tenth current terminals and a fifth control terminal, wherein the fifth control terminal is coupled to the eighth current terminal;
a first resistor coupled between the eighth current terminal and the tenth current terminal; and
a second resistor coupled between the seventh current terminal and the ninth current terminal.

6. The power circuit of claim 5, wherein the second resistor has a variable resistance determined by a voltage at the fifth control terminal.

7. The power circuit of claim 1, wherein the first transistor, the second transistor, the third transistor and the fourth transistor are each n-channel field effect transistors (NFETs).

8. The power circuit of claim 1, wherein a maximum voltage rating of the first transistor is at least five times a maximum voltage rating of the second transistor.

9. The power circuit of claim 8, wherein a maximum voltage rating of the third transistor is equal to the maximum voltage rating of the first transistor, and a maximum voltage rating of the fourth transistor is equal to the maximum voltage rating of the second transistor.

10. The power circuit of claim 2, wherein the third control terminal is coupled to a constant DC voltage supply.

11. An integrated circuit, comprising:
a substrate having a first conductivity type;
a diffusion layer disposed upon the substrate, wherein the diffusion layer has a second conductivity type, and the diffusion layer is electrically unconnected and has a floating voltage;
a bulk layer disposed upon the diffusion layer, wherein the bulk layer has the first conductivity type;
a doped well disposed upon the bulk layer, wherein the doped well has the second conductivity type; and
a control terminal disposed upon the bulk layer, wherein the control terminal is electrically isolated from the doped well.

12. The integrated circuit of claim 11, wherein the first conductivity type is n-type, and the second conductivity type is p-type.

13. The integrated circuit of claim 11, wherein the doped well forms a source of a transistor.

14. The integrated circuit of claim 13, wherein the control terminal is a gate of the transistor.

15. The integrated circuit of claim 14, wherein the doped well is a first doped well, and the integrated circuit is further comprising a second doped well having the first conductivity type and a third doped well having the second conductivity type, and the second and third doped wells are disposed upon the bulk layer and form a source of the transistor.

16. The integrated circuit of claim 15, wherein the transistor is an n-channel field effect transistor (NFET).

17. A method for manufacturing an integrated circuit, comprising:
forming a substrate having a first conductivity type;
forming a diffusion layer upon the substrate, wherein the diffusion layer has a second conductivity type, and the diffusion layer is electrically unconnected and has a floating voltage;
forming a bulk layer upon the diffusion layer, wherein the bulk layer has the first conductivity type;
forming a doped well upon the bulk layer, wherein the doped well has the second conductivity type; and
forming a control terminal upon the bulk layer, wherein the control terminal is electrically isolated from the doped well.

18. The method of claim 17, wherein the first conductivity type is n-type, and the second conductivity type is p-type.

19. The method of claim 17, wherein the doped well forms a source of a transistor, and the control terminal is a gate of the transistor.

20. The method of claim 19, wherein the doped well is a first doped well, and the method is further comprising forming a second doped well having the first conductivity type and a third doped well having the second conductivity type, in which the second and third doped wells are formed on the bulk layer and form a source of the transistor.
